(19) United States
(12) Patent Application Publication
(10) Pub. No.: US 2011/0120366 A1
(43) Pub. Date: May 26, 2011

(54) SUSCEPTOR, FILM FORMING APPARATUS AND METHOD

(76) Inventors: Shinya HIGASHI, Kanagawa (JP); Hironobu Hirata, Shizuoka (JP)

(21) Appl. No.: 12/949,326

(22) Filed: Nov. 18, 2010

(30) Foreign Application Priority Data
Nov. 20, 2009 (JP) 2009-265434

(51) Int. Cl. C30B 25/12

(52) U.S. Cl. 117/94; 118/723 R; 118/64

(57) ABSTRACT

An outer peripheral portion of the silicon wafer is supported by the first susceptor part. The second susceptor part is a close fit in the opening of the first susceptor part to support a portion other than the outer peripheral portion of the silicon wafer. The second susceptor part comes into contact with the outer peripheral portion of the first susceptor part and is disposed in such a manner that a clearance having a predetermined size is formed between the first susceptor part and the second susceptor part and between the opening and the outer peripheral portion thereof. A gas exiting the clearance, which was expanded by heating, is expelled into the chamber via through holes.

### CROSS-REFERENCE TO RELATED APPLICATION

The entire disclosure of the Japanese Patent Application No. 2009-265434, filed on Nov. 20, 2009 including specification, claims, drawings and summary, on which the Convention priority of the present application is based, are incorporated herein in its entirety.

### FIELD OF THE INVENTION

The present invention relates to a susceptor, and a film forming apparatus and method using the same.

### BACKGROUND

An epitaxial growth technique has been utilized in the process for manufacturing semiconductor devices such as a power device, for example an IGBT (Insulated Gate Bipolar Transistor) which requires a crystal film relatively large in thickness.

In order to fabricate an epitaxial wafer which is large in film thickness and in high yield, improving a film deposition rate is required by causing new material gases to come into contact with the surface of a uniformly-heated wafer successively. Therefore, growing layers epitaxially has been practiced with the wafer rotated at high speed (refer to, for example, Japanese Patent Application Laid-Open No. Hei 5 (1993)-152207).

In the Japanese Patent Application Laid-Open No. Hei 5 (1993)-152207, a ring-shaped susceptor for supporting the wafer is fitted to a susceptor support, and a rotating shaft connected to the susceptor support is rotated to turn the wafer. In this technique, the susceptor has a structure in which the outer peripheral portion of the wafer is received in a counter bore provided on an inner peripheral side of the susceptor. Namely, only an extremely narrow portion of the outer peripheral portion of the back surface of the wafer is in contact with the susceptor, and the remaining portion thereof is exposed toward the surface of a uniform heating plate which heats the back surface of the wafer. In such a structure, the wafer is contaminated by contaminants such as metal atoms developed in heating and rotating sections, thus causing a possibility that the electrical characteristics of an epitaxial film may be degraded.

Further, the Japanese Patent Application Laid-Open No. Hei (1993)-152207 shows that a mixture of a material gas and a carrier gas introduced into a reaction chamber flows radially from the central part of the upper surface of the wafer and is swept to the outer peripheral portion thereof by a centrifugal force due to the rotation of the wafer, followed by being expelled to the outside of the reaction chamber through exhaust holes. In this structure, however, the susceptor is ring shaped, whereby part of the swept gas flows into an opening of the susceptor through a clearance between the outer peripheral portion of the wafer and the susceptor, so that an epitaxial film is formed between the wafer and the susceptor. Accordingly, the wafer sticks to the susceptor, thus resulting in not only restraining wafer transfer but also the occurrence of a crystal defect called a slip. The slip causes warpage of the wafer and causes a leak in an IC device, thus reducing the yield of the IC device significantly.

Therefore, a susceptor comprising a ring-shaped first susceptor part which supports an outer peripheral portion of a wafer, and a disk-shaped second susceptor part that is close fit in an opening of the first susceptor part have been proposed. According to the susceptor, since the opening of the first susceptor part is blocked off by the second susceptor part, the wafer can be prevented from being contaminated by contaminants developed in heating and rotating sections. Furthermore, the flow of a mixed gas passing through a clearance between an outer peripheral portion of the wafer and the susceptor can be cut off.

The susceptor is heated by the heater 120 positioned within the reaction chamber underneath the susceptor. Since the wafer is in contact with the first susceptor part and the second susceptor part, the wafer is heated through these susceptor parts. If the temperature distribution of the wafer is not uniform at this time, the thickness of an epitaxial film to be formed will also not be uniform. Furthermore, when the wafer is not placed in a predetermined position, forming a film having a predetermined thickness uniformly on the surface of the wafer is impossible. Therefore, there has been a demand for a technique enabling epitaxial growth by making uniform temperature distribution when the wafer is placed in a predetermined position.

### SUMMARY

In one aspect of the present invention, A susceptor comprising: a first susceptor part that is ring shaped; a second susceptor part that is a close fit in the opening of the first susceptor part and is in contact with the outer peripheral portion of the first susceptor part; a clearance of a predetermined size between the first susceptor part and the second susceptor part and between the opening and the outer peripheral portion; and holes through which a gas in the clearance is expelled.

In another aspect of the invention a susceptor on which a substrate is to be placed when a predetermined process is performed on the substrate, the susceptor comprising: a first susceptor part that is ring shaped; the first susceptor part supporting an outer peripheral portion of the substrate; and a second susceptor part which is in contact with an outer peripheral portion of the first susceptor part and blocks off an opening of the first susceptor part; wherein the second susceptor part is disposed in such a manner that a clearance of a predetermined size is formed between the substrate and the second susceptor part in which the substrate is supported by the first susceptor part; and disposed in such a manner that a clearance of a size substantially equal to the predetermined size is formed adjoining the former clearance between the first susceptor part and the second susceptor part; and wherein holes through are provided which expel gas in these clearances.

In another aspect of the invention, a film forming apparatus comprising: a film forming chamber into which a substrate is to be positioned; a susceptor on which the substrate is to be placed within the film forming chamber; and a heating section which heats the substrate through the susceptor; wherein the susceptor comprises: a first susceptor part that is ring shaped; a second susceptor part that is a close fit in the opening of the first susceptor part and is in contact with the outer peripheral portion of the first susceptor part; a clearance of a predetermined size between the first susceptor part and the second susceptor part and between the opening and the outer peripheral portion; and holes through which expel gas in the clearance.

In another aspect of the invention, a film forming apparatus comprising: a film forming chamber into which a substrate is to be carried; a susceptor on which the substrate is to be placed within the film forming chamber; and a heating section which heats the substrate through the susceptor, wherein the susceptor comprises: a first susceptor part that is ring shaped, the first susceptor supporting an outer peripheral portion of the substrate; and a second susceptor part which is provided in contact with an outer peripheral portion of the first susceptor part and blocks off an opening of the first susceptor part, wherein the second susceptor part is disposed in such a manner that a clearance of a predetermined size is formed between the substrate and the second susceptor part in which the substrate is supported by the first susceptor part, and disposed in such a manner that a clearance of a size substantially equal to the predetermined size is formed adjoining the former clearance between the first susceptor part and the second susceptor part, and wherein the susceptor is provided with holes through which expels gas in the clearances.

In another aspect of the present invention, a film forming method for forming a predetermined film on a substrate while heating the substrate within a film forming chamber, the method comprising: supporting an outer peripheral portion of the substrate by a first susceptor part that is ring shaped; causing a second susceptor part that is close fit in an opening of the first susceptor part and supports a portion other than the outer peripheral portion of the substrate to contact an outer peripheral portion of the first susceptor part, and to be disposed in such a manner that a clearance having a predetermined size is formed between the first susceptor part and the second susceptor part and between the opening and the outer peripheral portion of the first susceptor part; and forming the predetermined film while expelling gas in the clearance.

In yet another aspect of the present invention, a film forming method for forming a predetermined film on a substrate while heating the substrate within a film forming chamber, the method comprising: supporting an outer peripheral portion of the substrate by a first susceptor part that is ring shaped; causing a second susceptor part that blocks off an opening of the first susceptor part to be provided in contact with an outer peripheral portion of the first susceptor part, and to be formed in such a manner that a clearance of a predetermined size is formed between the substrate and the second susceptor part in which the substrate is supported by the first susceptor part, and in such a manner that a clearance of a size substantially equal to the predetermined size is formed between the first susceptor part and the second susceptor part, thus expelling the gas in these clearances while forming the predetermined film.

### BRIEF DESCRIPTION OF THE DRAWINGS

FIG. 1 is a typical cross-sectional view of a single wafer film forming apparatus according to a first embodiment of the present invention.

FIG. 2 is a cross-sectional view of the silicon wafer as placed on the susceptor.

FIG. 3 is one example showing a relationship between the change in the temperature of the wafer and the rising force acting thereon.

FIG. 4 is a plan view of the first susceptor part.

FIG. 5 is another example of the susceptor according to the present embodiment.

FIG. 6 is a partly enlarged sectional view of FIG. 5.

FIG. 7 is a typical cross-sectional view of a single wafer film forming apparatus according to a second embodiment.

FIG. 8 is a plan view of the second susceptor part.

FIG. 9 is a typical cross-sectional view of a single wafer film forming apparatus according to a third embodiment.

### DETAILED DESCRIPTION OF EMBODIMENTS

The following embodiments may be summarized as follows.

According to a susceptor of the present invention, it is possible to reduce sticking of a wafer thereto and metal contamination of the wafer, and to realize a uniform temperature distribution of the wafer and a prevention of a position displacement of the wafer.

According to a film forming apparatus of the present invention, a film having a uniform film thickness can be formed while reducing the occurrence of a slip.

According to a film forming method of the present invention, a film having a uniform film thickness can be formed while reducing the occurrence of a slip.

### First Embodiment

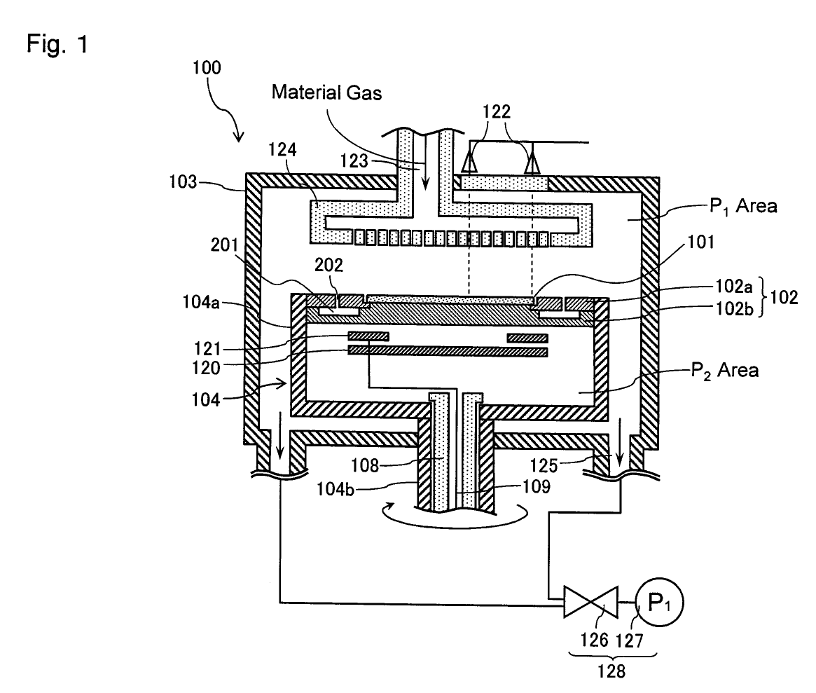

FIG. 1 is a typical cross-sectional view of a single wafer film forming apparatus 100 according to a first embodiment of the present invention.

In the present embodiment, a silicon wafer 101 is used as a substrate. The substrate however is not limited to this material but may be a wafer made of other materials.

The film forming apparatus 100 has a chamber 103 used as a film forming chamber.

A gas supply part 123, which supplies a material gas for growing a crystal film on the surface of the heated silicon wafer 101, is provided at an upper part of the chamber 103. A shower plate 124 in which holes for delivery of the material gas are formed in large numbers, is connected to the gas supply part 123. The shower plate 124 is disposed opposite to the surface of the silicon wafer 101 so that the material gas is supplied to the surface of the silicon wafer 101.

A plurality of gas exhausts 125 for expelling the post-reaction material gas are provided at a lower part of the chamber 103. The gas exhaust parts 125 are connected to an exhaust mechanism 128 consisting of a control valve 126 and a vacuum pump 127. The exhaust mechanism 128 is controlled by a control mechanism (not shown) to control or adjust pressure inside the chamber 103 to predetermined level.

A susceptor 102 according to the present embodiment is provided at an upper part of a rotating section 104 inside the chamber 103. Since the susceptor 102 is placed under high temperature, therefore, high-purity SiC is used. However, another material capable of withstanding the high temperatures may also be used.

The rotating section 104 has a cylindrical part 104a and a rotating shaft 104b. The rotating shaft 104b is rotated by a motor (not shown) so that the susceptor 102 is rotated through the cylindrical part 104a.

In FIG. 1, the cylindrical part 104a has a structure in which the upper part thereof is made open, but is formed with a hollow area (hereinafter called P₂ area) with its upper part being covered by the susceptor 102. Assuming now that the inside of the chamber 103 is a P₁ area, the P₂ area becomes an area substantially separated from the P₁ area by the susceptor 102.

An inheater 120 and an outheater 121 used as a heating section are provided in the P₂ area. These heaters are supplied with power by a wiring 109 that passes through the inside of an approximately cylindrical quartz-made shaft 108 provided within the rotating shaft 104b and heats the silicon wafer 101 from the back surface thereof through the susceptor 102.

The temperature of the surface of the silicon wafer 101, which changes by heating, is measured by a radiation thermometer 122 provided above the chamber 103. Incidentally, the shower plate 124 is made of transparent quartz to thereby make the plate 124 avoid interference with the measurement of the temperature by the radiation thermometer 122. The temperature data is sent to the control mechanism (not shown) and thereafter fed back for output control of the inheater 120 and the outheater 121. Thus, the silicon wafer 101 can be heated to a desired temperature.

The rotating shaft 104b of the rotating section 104 is provided so as to extend to the outside of the chamber 103 and connected to a rotation mechanism (not shown). The cylindrical part 104a is rotated at a predetermined number of revolutions to thereby enable the rotation of the susceptor 102, further, to make it possible to rotate the silicon wafer 101 supported by the susceptor 102. The cylindrical part 104a preferably has an axis which passes through the center of the silicon wafer 101 and is perpendicular to the silicon wafer 101 to rotate about the axis.

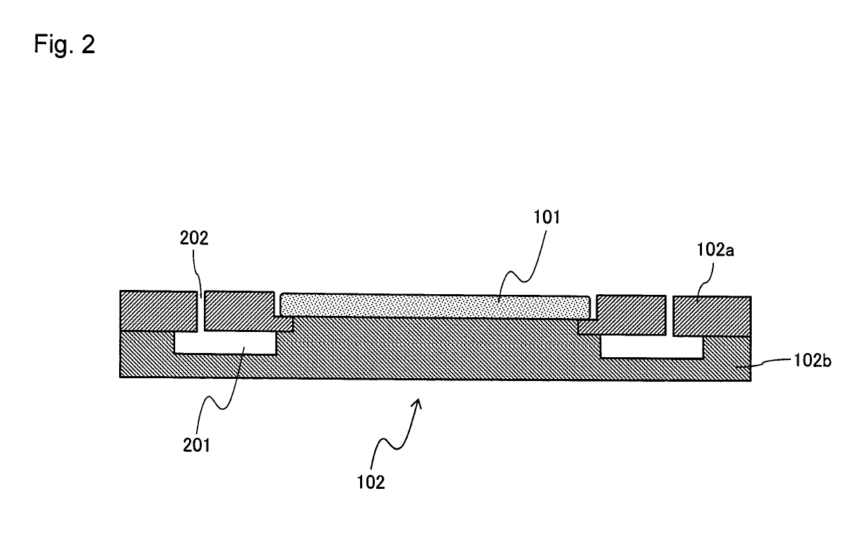

FIG. 2 is a cross-sectional view of a state in which the silicon wafer 101 is placed on the susceptor 102.

As shown in FIG. 2, the susceptor 102 has a ring-shaped first susceptor part 102a which supports the outer peripheral portion of the silicon wafer 101, and a second susceptor part 102b which blocks off an opening of the first susceptor part 102a.

When the susceptor 102 is placed within the chamber 103 as shown in FIG. 1, the opening of the first susceptor part 102a is blocked off by the second susceptor part 102b, thereby making it possible to prevent the silicon wafer 101 from being contaminated by contaminants developed in the P₂ area. Further, the material gas can be prevented from entering into the P₂ area through a clearance defined between the outer peripheral portion of the silicon wafer 101 and the susceptor 102. Accordingly, an epitaxial film is prevented from being formed between the silicon wafer 101 and the susceptor 102, thus making it possible to reduce sticking of the silicon wafer 101 to the susceptor 102 and the occurrence of a slip.

In a state in which the second susceptor part 102b is close fit in the opening of the first susceptor part 102a, a clearance 201 is defined in the outer peripheral portion of the susceptor 102, i.e., between the first susceptor part 102a and the second susceptor part 102b. The size of the clearance 201, i.e., the distance between the first susceptor part 102a and the second susceptor part 102b in the clearance 201 can be set to, for example, 0.5 mm to 2.0 mm. The provision of the clearance 201 can provide the following advantageous effects.

When the silicon wafer 101 is placed on the susceptor 102 as shown in FIG. 2, the silicon wafer 101 is brought into contact with the first susceptor part 102a and the second susceptor part 102b. In this state, the silicon wafer 101 is heated from the back surface thereof via the susceptor 102 by means of the inheater 120 and outheater 121 both shown in FIG. 1. At this time, the second susceptor part 102b is first heated by the inheater 120 and the outheater 121.

If clearance 201 is not provided, the outer peripheral portion of the silicon wafer 101 is heated through the first susceptor part 102a which is heated through the second susceptor part 102b. On the other hand, a portion other than the outer peripheral portion of the silicon wafer 101 is heated through the second susceptor part 102b. If the temperature of the outer peripheral portion of the silicon wafer 101 becomes high, the thickness of the epitaxial film will not be uniform and thermal stress will be concentrated on the portion where the silicon wafer 101 and the first susceptor part 102a come into contact with each other, thereby causing the occurrence of breakage of the susceptor 102 and slip. This problem is however solved by providing the clearance 201.

When the clearance 201 is provided between the first susceptor part 102a and the second susceptor part 102b, the outer peripheral portion of the silicon wafer 101 is heated through the first susceptor part 102a subjected to heat transfer from the second susceptor part 102b via an atmosphere gas existing in the clearance 201. SiC that forms the first susceptor part 102a and the second susceptor part 102b is lower in thermal resistance than the atmosphere gas. Accordingly, the atmosphere gas high in thermal resistance intervenes between the two susceptor parts by providing the clearance 201, and hence heat transferred from the second susceptor part 102b to the first susceptor part becomes also low. Consequently, a rise in the temperature at the outer peripheral portion of the silicon wafer 101 is suppressed.

The first susceptor part 102a is provided with holes (through holes) 202 positioned in a direction orthogonal to a radial direction thereof. This is effective in preventing a position displacement of the silicon wafer 101.

The atmosphere gas in the clearance 201 thermally expands with the rise in the temperature due to heating. With no provision of the holes 202, the first susceptor part 102a is pushed up by the pressure of the atmosphere gas. This causes a force (hereinafter called rising force) for pushing up the silicon wafer 101 from the back surface thereof to act on the silicon wafer 101 that is in contact with the first susceptor part 102a. As a result, the silicon wafer 101 is shifted from its predetermined position. Since the holes 22 are provided, however, the thermally-expanded atmosphere gas is degassed from the holes 202 and the first susceptor part 102a is not pushed up. Thus, no position displacement occurs in the silicon wafer 101.

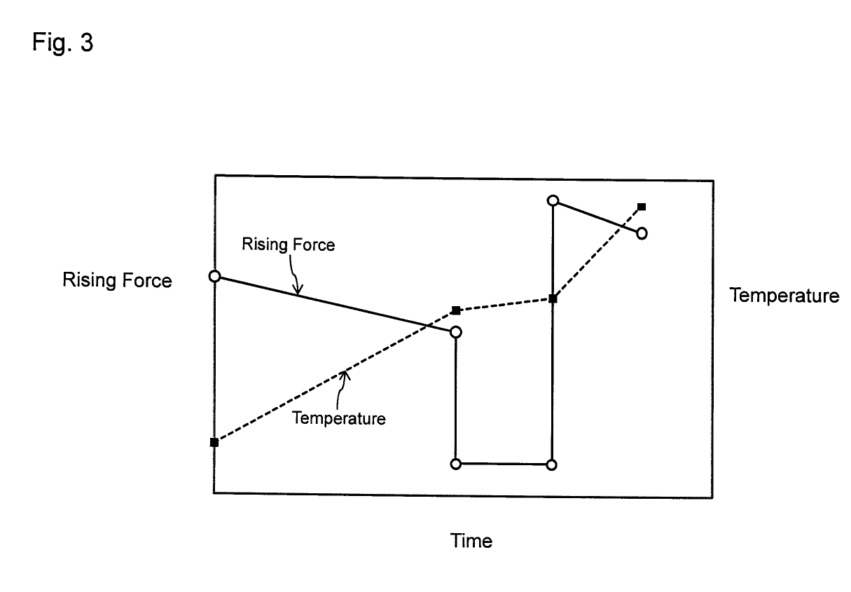

FIG. 3 is one example showing a relationship between a change in the temperature of the wafer and a rising force acts thereon. As shown in this figure, the rising force that acts on the wafer changes with a temperature gradient. When, for example, a silicon wafer having a mass of 54 g is heated from 200° C. to 700° C. over about 700 seconds, the rising force becomes a magnitude from 1.5×10⁻² gf to 2×10⁻² gf. Thereafter, the rising force decreases as a heating rate is reduced, but increases as the heating rate is raised again. When the silicon wafer is heated from 750° C. to 1100° C. over 200 seconds or so, for example, the rising force reaches even from 2.5×10⁻² gf to 2.8×10⁻² gf. The size of holes, the number thereof and their layout appropriate for suppression of the occurrence of such a rising force are determined by, for example, a simulation using an unsteady thermohydraulic analysis. If the mass of the wafer is larger than the maximum value of the rising force, no position displacement occurs in the wafer. Accordingly, the size of holes, the number thereof and their layout, which satisfy this relationship, may be determined.

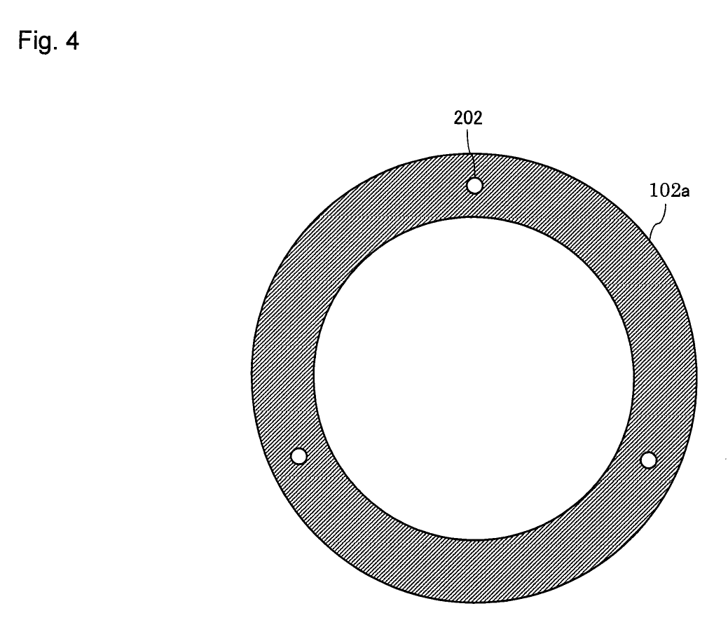

FIG. 4 is a plan view of the first susceptor part 102a shown in FIG. 2. As shown in FIG. 4, the holes 202 can be provided at three positions which are decided by dividing the first susceptor part 102a into three equal parts. According to the above simulation, if the diameter of each hole 202 is 2 mm where the diameter of the silicon wafer 101 is 200 mm, it is then possible to sufficiently suppress the rising force of the wafer. Further, according to the discussions of the present inventors, even when the diameter of the silicon wafer 101 is 300 mm, the diameter of each hole 202 is set to 2 mm and the holes are provided at three positions which are decided by dividing the first susceptor part 102a into three equal parts, thereby making it possible to sufficiently suppress the rising force of the silicon wafer 101.

Preferably, the size of holes, the number thereof and their layout are suitably set according to the diameter of the wafer, the distribution of stress applied to the wafer, and the like.

If each hole is too small, the hole may be blocked off by the epitaxial growth film and further, stress may be concentrated on each hole portion to cause breakage of the susceptor. In addition, since excessively small holes are difficult to be manufactured, the size thereof is required to be decided in consideration of ease of manufacturing.

On the other hand, if each hole is excessively large, a temperature distribution occurs in the susceptor and the thickness of the formed epitaxial film will not be uniform. If the diameter of each hole exceeds one-fifth the size (difference between the outer diameter and the inner diameter) in the widthwise direction of the ring-shaped first susceptor part, for example, a temperature distribution occurs in the susceptor. Accordingly, the diameter of the hole may preferably be set not to exceed this value. When the diameter of the silicon wafer 101 is 200 mm, for example, the size in the widthwise direction, of the first susceptor part 102a can be set to 23 mm. At this time, the diameter of the hole may preferably range from 1.5 mm or more and 4.5 mm or less.

The number of the holes is not limited to three, but may be one or more. A plurality of holes may, however, be provided where the uniform heating characteristic of the susceptor is taken into consideration. Further, the number of the holes is preferably three in particular in terms of the prevention of occurrence of the temperature distribution in the susceptor.

The locations where the holes are to be provided are determined in consideration of the temperature and stress distributions of the susceptor. If each hole is located in a position large in temperature gradient then tensile stress increases in the circumferential direction of the susceptor thus causing a crack. If each hole is located in a position large in the stress distribution of the susceptor, a crack can occur. Accordingly, the holes may be provided at the positions as small in temperature gradient as possible and the positions on which the stress is not concentrated.

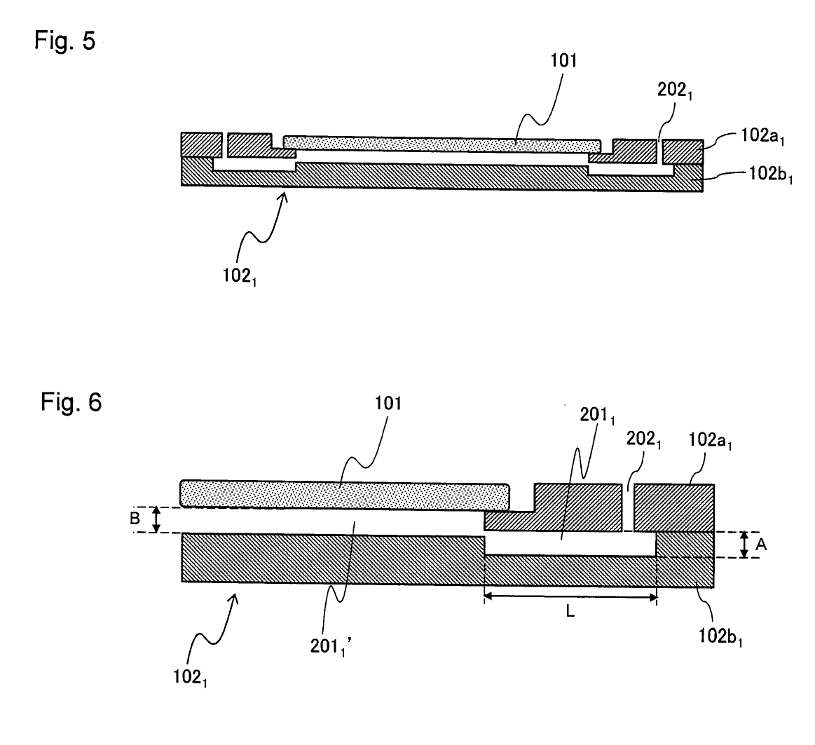

FIG. 5 is another example of the susceptor according to the present embodiment. FIG. 5 shows a state in which a silicon wafer 110 is placed on a susceptor 102₁. FIG. 6 is a partly enlarged sectional view of FIG. 5.

As shown in FIGS. 5 and 6, the susceptor 102₁ has a ring-shaped first susceptor part 102a₁ which supports an outer peripheral portion of the silicon wafer 101, and a second susceptor part 102b₁ which is provided in contact with an outer peripheral portion of the first susceptor part 102aᵢ and blocks off an opening of the first susceptor part 102a₁. According to this structure, advantageous effects similar to those of the susceptor 102 shown in FIG. 2 can be obtained.

Namely, when the susceptor 102₁ is placed within the chamber 103 shown in FIG. 1, the opening of the first susceptor part 102a₁ is blocked off by the second susceptor part 102b₁, so that the silicon wafer 101 can be prevented from being contaminated by contaminants developed in the P₂ area. Further, a material gas can be prevented from entering into the P₂ area through a clearance defined between the outer peripheral portion of the silicon wafer 101 and the susceptor 102₁. Accordingly, an epitaxial film is prevented from being formed between the silicon wafer 101 and the susceptor 102₁, thus making it possible to reduce sticking of the silicon wafer 101 to the susceptor 102₁ and the occurrence of a slip.

The susceptor 102₁ is similar to the susceptor 102 shown in FIG. 2 in that it has a gap or clearance 201₁ between the first susceptor part 102a₁ and the second susceptor part 102b₁. In the susceptor 102₁, however, a clearance 201₁′ is formed between the silicon wafer 101 and the second susceptor part 102b₁.

The clearance 201₁′ is a space continuous to the clearance 201₁. Namely, a shielding portion for dividing off these spaces is not provided between the clearance 201₁ and the clearance 201_{1′}. Providing the clearance 201₁′ makes it possible to prevent a position displacement of the silicon wafer 101 more effectively. This effect will be explained in detail below.

In a structure where the silicon wafer contacts to the second susceptor part, an atmosphere gas may be sandwiched between the silicon wafer and the second susceptor part upon placing the silicon wafer on the susceptor. In this case, the pressure of the gas sandwiched in between rises due to the weight of the silicon wafer. Thereafter, the gas is degassed from between the silicon wafer and the second susceptor part, but the silicon wafer is shifted from its predetermined position. On the other hand, with a structure that the silicon wafer 101 is supported by the first susceptor part 102a₁ and the clearance 201₁′ is provided between the silicon wafer 101 and the second susceptor part 102b₁ as shown in FIG. 6, the above problem can be solved.

Furthermore, if the silicon wafer is in contact with the second susceptor part, warpage occurs in the silicon wafer due to thermal deformation by heating, so that a film may not be formed while the silicon wafer is being rotated. With a structure that, however, the clearance 201₁′ is provided between the silicon wafer 101 and the second susceptor part 102b₁ as shown in FIG. 6, such a problem can also be solved.

Further, since the shielding portion for dividing off these spaces is not provided between the clearance 201₁ and the clearance 201₁′, heat is prevented from being transferred from the second susceptor part 102b₁ to the silicon wafer 101 and the first susceptor part 102a₁ through the masking, so that a specific portion of the silicon wafer 101 can also be prevented from rising in temperature.

When the silicon wafer 101 is placed over the susceptor 102₁, the outer peripheral portion of the silicon wafer 101 comes into contact with the first susceptor part 102a₁. In this state, the silicon wafer 101 is heated from the back surface thereof via the susceptor 102₁ by means of the inheater 120 and outheater 121 both shown in FIG. 1. At this time, the second susceptor part 102b₁ is first heated by the inheater 120 and the outheater 121. Thereafter, the silicon wafer 101 is heated through the atmosphere gas existing in both the clearance 201₁ and the clearance 201₁′ and through the first susceptor part 102a₁ by using heat propagating from the second susceptor part 102b₁. The way in which the silicon wafer 101 is heated will be described in further detail below.

A portion other than the outer peripheral portion of the silicon wafer 101 is heated via the atmosphere gas in the clearance 201₁′ by using heat propagating from the second susceptor part 102b₁. On the other hand, since the outer peripheral portion of the silicon wafer 101 is in contact with the first susceptor part 102a₁, the portion is heated through the first susceptor part 102a₁. In this case, since the clearance 201₁ is provided between the first susceptor part 102a₁ and the second susceptor part 102b₁, the outer peripheral portion of the silicon wafer 101 is heated through the following two routes.

One of the two routes is a route in which the silicon wafer 101 is heated through the atmosphere gas in the clearance 201₁ and heated through the first susceptor part 102a₁ by using heat propagating from the second susceptor part 102b₁. Another is a route in which the first susceptor part 102a₁ is heated through a portion brought into contact with the second susceptor part 102b₁ and the silicon wafer 101 is then heated. In both the routes, the second susceptor part 102b₁ is first heated by the heaters and the thus-generated heat is then transferred to the first susceptor part 102a₁, but a portion of the first susceptor part 102a₁, which is close to the outer peripheral portion of the silicon wafer 101, is heated through the atmosphere gas in the clearance 201₁. On the other hand, a portion of the first susceptor part 102a₁, to which heat is directly transferred from the second susceptor part 102b₁, corresponds to a portion to which the second susceptor part 102b₁ contacts, i.e., the outer peripheral portion of the first susceptor part 102a₁, which spaced away from the outer peripheral portion of the silicon wafer 101. Namely, providing the clearance 201₁ makes the temperature of the portion, of the first susceptor part 102a₁, to which the outer peripheral portion of the silicon wafer 101 contacts, lower than that in a case where the clearance 201₁ is not provided.

Preferably, a height A of the clearance 201₁ and a height B of the clearance 201_{1′} be substantially equal to each other, in FIG. 6. Since the thermal resistance of the atmosphere gas in these clearances is higher than that of SiC, a temperature distribution of the silicon wafer 101 can be adjusted by adjusting the heights of the clearances. Namely, the temperature distribution of the silicon wafer 101 can be made uniform by equalizing the height A and the height B in relation to each other. The heights A and B can be set to an equal value within a range from 0.5 mm to 2.0 mm, for example, but are preferably set as appropriate according to the pressure in the chamber. The temperature distribution of the silicon wafer 101 can be adjusted by a lateral direction length L of the clearance 201₁. If the length L is made long, the amount of heat transferred from the first susceptor part 102a₁ to the silicon wafer 101, which is transferred from the second susceptor part 102b₁ via the contact portion between the first and second susceptor parts, is reduced so that the temperature of the outer peripheral portion of the silicon wafer 101 is lowered.

The first susceptor part 102a₁ is provided with holes (through holes) 202₁ in a direction orthogonal to a radial direction thereof. This is effective in preventing a position displacement of the silicon wafer 101.

The atmosphere gas in the clearances 201₁ and 201₁′ thermally expands with a rise in the temperature due to heating. If the holes 202₁ are not provided, the first susceptor part 102a₁ is pushed up by the pressure of the atmosphere gas. This causes a rising force to act on the silicon wafer 101 that is in contact with the first susceptor part 102a₁. As a result, the silicon wafer 101 is shifted from the predetermined position thereof. If, however, the holes 202₁ are provided, since the thermally-expanded atmosphere gas is removed therefrom, the first susceptor part 102a₁ is not pushed up. Thus, no position displacement occurs in the silicon wafer 101.

The size of holes, the number thereof and their layout can be decided in a manner similar to the case of the susceptor 102a shown in FIG. 2. When the diameter of the silicon wafer 101 is 200 mm, for example, the diameter of each hole 202₁ is set to 2 mm and the holes 202₁ are provided at three positions which are determined by dividing the first susceptor part 102a₁ into three equal parts, whereby the rising force of the silicon wafer 101 can be suppressed sufficiently. This is similar in a case where the diameter of the silicon wafer 101 is 300 mm.

Preferably, the size of holes, the number thereof and their layout are suitably set in accordance with the diameter of the wafer, the distribution of stress applied to the wafer, and the like.

If each hole is too small, the hole may be blocked off by the epitaxial growth film. Further, stress may be concentrated on each hole portion to cause breakage of the susceptor. In addition, since an excessively small hole size is difficult to be manufactured, the size thereof is required to be decided in consideration of ease of manufacturing. On the other hand, if each hole is excessively large, a temperature distribution occurs in the susceptor and the thickness of the formed epitaxial film will not be uniform. When the diameter of each hole exceeds one-fifth the size (difference between the outer diameter and the inner diameter) in the widthwise direction of the ring-shaped first susceptor part, for example, a temperature distribution occurs in the susceptor. Accordingly, the diameter of the hole may preferably be set so as not to exceed this value. When the diameter of the silicon wafer 101 is 200 mm, for example, the size in the widthwise direction, of the first susceptor part 102a can be set to 23 mm. At this time, the diameter of the hole may preferably range from 1.5 mm or more and 4.5 mm or less.

The number of the holes is not limited to three, but may be one or more. A plurality of holes may, however, be provided where the uniform heating of the susceptor is taken into consideration. Further, the number of the holes is preferably three in particular in terms of the prevention of occurrence of the temperature distribution in the susceptor.

The locations where the holes are to be provided are determined in consideration of the temperature and stress distributions of the susceptor. If each of the holes is located in a temperature gradient position susceptible to fluctuating temperatures, then, tensile stress increases in the circumferential direction of the susceptor, thus causing a crack. If the hole is located in a position large within the stress distribution of the susceptor, this can also lead to a crack. Accordingly, the holes are provided at the positions as small in temperature gradient as possible and the positions on which the stress is not concentrated.

Incidentally, the first susceptor part 102a₁ and the second susceptor part 102b₁ can be brought into a structure in which they are combined together after having been formed discretely, but may be taken as a structure in which they are brought into integral form from the beginning.

According to the susceptor of the present embodiment as described above, since a clearance is provided between the first susceptor part and the second susceptor part, the temperature of the first susceptor part brought into contact with the outer peripheral portion of the wafer becomes lower than in a susceptor without a clearance when the first susceptor part is heated by the contact of the first susceptor part with the outer peripheral portion thereof. Thus, since the temperature of the outer peripheral portion of the wafer does not suddenly rise more than the temperature at the portion other than the outer peripheral portion, the uniform temperature distribution of the wafer is not interfered. Since the concentration of thermal stress on the portion where the wafer and the first susceptor part come into contact with each other is reduced, breakage of the susceptor and the occurrence of a slip in the wafer are reduced.

According to the susceptor of the present embodiment, since the first susceptor part is provided with the holes, the atmosphere gas in the clearance between the first susceptor part and the second susceptor part is degassed outside through the holes. Accordingly, the first susceptor part is not pushed up even if the atmosphere gas expands due to heating, thereby making it possible to prevent the occurrence of a position displacement in the wafer.

Further, according to the film forming apparatus using the susceptor of the present embodiment, a film uniform in film thickness can be grown on the wafer while the occurrence of a slip is being reduced.

### Second Embodiment

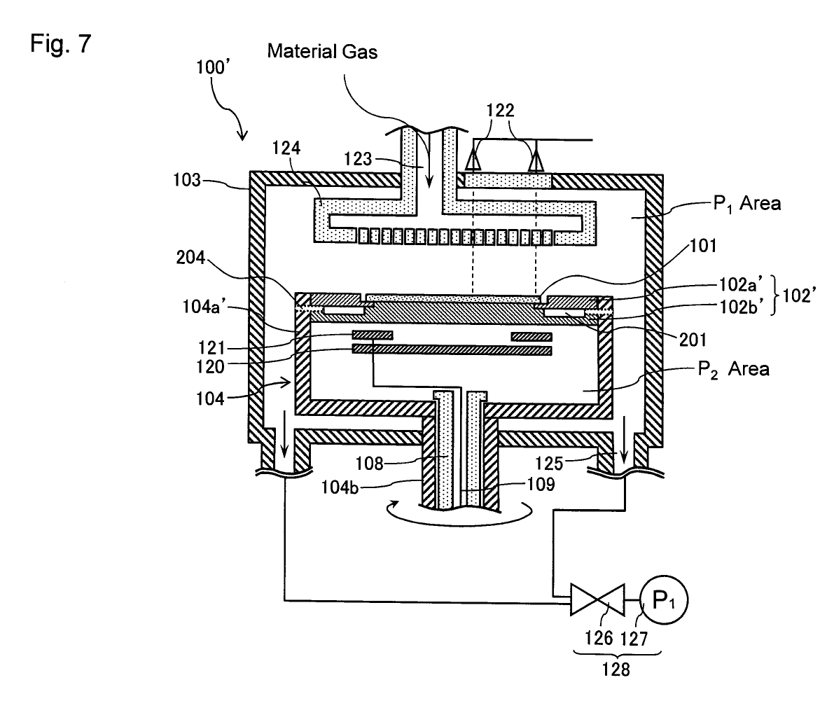

FIG. 7 is a typical cross-sectional view of a single wafer film forming apparatus 100′ according to a second embodiment. Incidentally, parts identified by the same reference numerals as those shown in FIG. 1 indicate the same parts respectively. A silicon wafer 101 is used as a substrate, but is not limited to it. A wafer composed of other materials may be used as the case may be.

The film forming apparatus 100′ has a chamber 103 used as a film forming chamber. The susceptor 102′ according to the present embodiment is provided at an upper part of a rotating section 104′ inside the chamber 103. Since the susceptor 102′ is placed under high temperature, high-purity SiC, for example, is used. The rotating section 104′ is provided with holes (through holes) 204 which connect grooves 203 to be described later and a P₁ area within the chamber 103.

The susceptor 102′ has a ring-shaped first susceptor part 102a′ which supports an outer peripheral portion of the silicon wafer 101, and a second susceptor part 102b′ which blocks off an opening of the first susceptor part 102a′.

When the susceptor 102′ is provided within the chamber 103 as shown in FIG. 7, the opening of the first susceptor part 102a′ is blocked off by the second susceptor part 102b′, thereby making it possible to prevent the silicon wafer 101 from being contaminated by contaminants developed in a P₂ area. Further, a material gas can be prevented from entering into the P₂ area through a clearance defined between the outer peripheral portion of the silicon wafer 101 and the susceptor 102′. Accordingly, an epitaxial film is prevented from being formed between the silicon wafer 101 and the susceptor 102′, thereby making it possible to reduce sticking of the silicon wafer 101 to the susceptor 102′ and the occurrence of a slip.

In a state in which the second susceptor part 102b′ is close fit in the opening of the first susceptor part 102a′, a clearance 201 is defined in the outer peripheral portion of the susceptor 102′, i.e., between the first susceptor part 102a′ and the second susceptor part 102b′. The height of the clearance 201, i.e., the distance between the first susceptor part 102a′ and the second susceptor part 102b′ can be set to, for example, 0.5 mm to 2.0 mm. When the outer peripheral portion of the silicon wafer 101 is high in temperature due to some causes, the silicon wafer 101 can be heated uniformly by providing the clearance 201. Namely, according to the configuration of the susceptor 102′, the outer peripheral portion of the silicon wafer 101 is heated through the first susceptor part 102a′ to which heat is transferred from the second susceptor part 102b′ through an atmosphere gas in the clearance 201. Here, SiC that configures the first susceptor part 102a′ and the second susceptor part 102b′ is lower in thermal resistance than the atmosphere gas. Accordingly, the atmosphere gas high in thermal resistance intervenes between the first and second susceptor parts, by providing the clearance 201, and hence the heat transferred from the second susceptor part 102b′ to the first susceptor part 102a′ also lowers. Thus, a rise in the temperature at the outer peripheral portion of the silicon wafer 101 is suppressed.

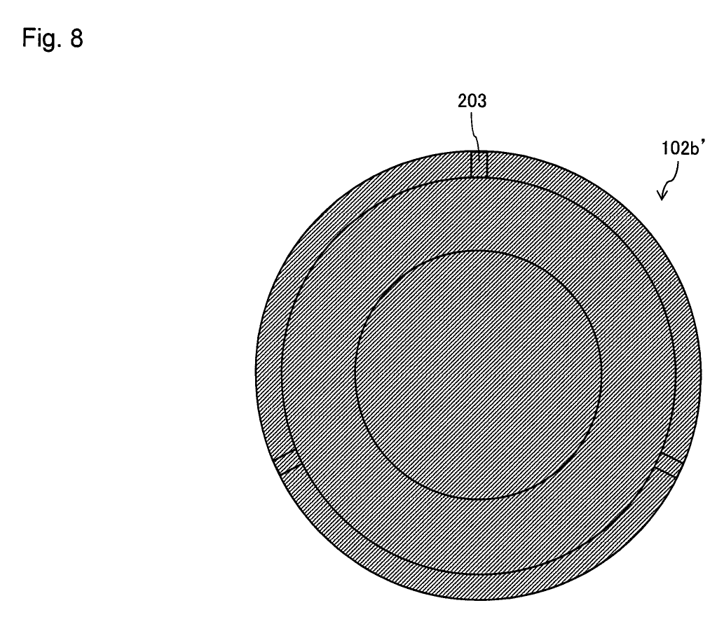

FIG. 8 is a plan view of the second susceptor part 102b′. As shown in the figure, the second susceptor part 102b′ is provided with the grooves 203. The susceptor 102′ is installed in such a manner that the grooves 203 communicate with the holes 204 provided in the rotating section 104′ as shown in FIG. 7. Such a configuration makes it possible to prevent a position displacement of the silicon wafer 101. This advantageous effect will be explained in detail below.

The atmosphere gas in the clearance 201 thermally expands with a rise in the temperature due to heating. If the grooves 203 and the holes 204 are not provided, the first susceptor part 102a′ is pushed up by the pressure of the atmosphere gas. This causes a rising force to act on the silicon wafer 101 that is brought into contact with the first susceptor part 102a′. As a result, the silicon wafer 101 is moved from its predetermined position. According to the configuration of the present embodiment, however, the thermally-expanded atmosphere gas is degassed into the P₁ area through the grooves 203 and the holes 204. This prevents the first susceptor part 102a′ from being pushed up, thereby preventing the occurrence of the position displacement of the silicon wafer 101. According to the configuration of the present embodiment as well, the possibility that the holes 204 may be blocked off by the epitaxial growth film is low. From this point of view, the present configuration has an advantage over the configuration described in the first embodiment.

Preferably, the size of each of the groove 203 and the holes 204, the numbers of the grooves 203 and the holes 204 and their layout are suitably set according to the diameter of the silicon wafer 101, the distribution of stress applied thereto, and the like.

If each of both grooves and holes is too small, stress may be concentrated around these areas and cause breakage of the susceptor. In addition, since excessively small grooves and holes are difficult to be processed, consideration of ease of manufacture is required. On the other hand, if the grooves and holes are excessively large, a temperature distribution occurs in the susceptor and hence the thickness of the formed epitaxial film will not be uniform. Accordingly, the size of each of the grooves and holes may preferably be determined in consideration of this point.

The numbers of the grooves and the holes may be one or more respectively, but may preferably be provided in plural form in consideration of the uniform heating and stress distribution of the susceptor.

According to the film forming apparatus of the present embodiment as described above, the susceptor is provided with the grooves. The susceptor is disposed in such a manner that the grooves and the holes defined in the rotating section communicate with one another. Thus, the atmosphere gas existing between the first susceptor part and the second susceptor part can be degassed outside through the grooves and the holes. Accordingly, the first susceptor part is not pushed up even if the atmosphere gas expands due to heating, thereby making it possible to prevent the occurrence of a position displacement of the wafer.

Incidentally, although the present embodiment has described the example in which the silicon wafer 101 is in contact with the second susceptor part 102b′, a clearance may be provided between the silicon wafer and the second susceptor part as shown in FIG. 5.

### Third Embodiment

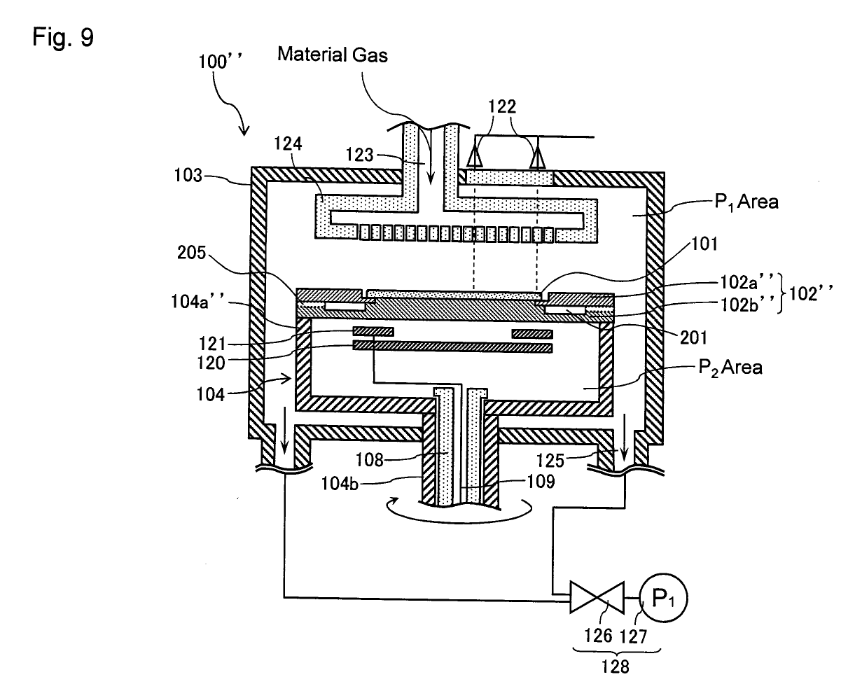

FIG. 9 is a typical cross-sectional view of a single wafer film forming apparatus 100″ according to a third embodiment. Incidentally, parts identified by the same reference numerals as those in FIG. 1 denote the same parts in FIG. 9. A silicon wafer 101 is used as a substrate. The substrate is not however limited to it, but may use a wafer made of other materials as the case may be.

The film forming apparatus 100″ has a chamber 103 used as a film forming chamber. A susceptor 102″ according to the present embodiment is provided above a rotating section 104″ inside the chamber 103. Since the susceptor 102″ is placed under high temperature, high-purity SiC, for example, or a similar material, is used.

The susceptor 102″ has a ring-shaped first susceptor part 102a″ which supports an outer peripheral portion of the silicon wafer 101, and a second susceptor part 102b″ which blocks off an opening of the first susceptor part 102a″.

Since the opening of the first susceptor part 102a″ is blocked off by the second susceptor part 102b″ as shown in FIG. 9, the silicon wafer 101 can be prevented from being contaminated by contaminants developed in a P₂ area. Further, a material gas can be prevented from entering into the P₂ area through a clearance defined between the outer peripheral portion of the silicon wafer 101 and the susceptor 102″. Accordingly, an epitaxial film can be prevented from being formed between the silicon wafer 101 and the susceptor 102″, thus making it possible to reduce sticking of the silicon wafer 101 to the susceptor 102″ and the occurrence of a slip.

In a state in which the second susceptor part 102b″ is close fit in the opening of the first susceptor part 102a″, a clearance 201 is defined in an outer peripheral portion of the susceptor 102″, i.e., between the first susceptor part 102a″ and the second susceptor part 102b″. The height of the clearance 201, i.e., the distance between the first susceptor part 102a″ and the second susceptor 102b″ in the clearance 201 can be set to, for example, 0.5 mm to 2.0 mm. When the outer peripheral portion of the silicon wafer 101 is high in temperature due to some causes, the silicon wafer 101 can be heated uniformly by providing the clearance 201. Namely, according to the configuration of the susceptor 102″, the outer peripheral portion of the silicon wafer 101 is heated by the first susceptor part 102a″ heat-transferred from the second susceptor part 102b″ through an atmosphere gas in the clearance 201. Here, SiC that configures the first susceptor part 102a″ and the second susceptor part 102b″ is lower in thermal resistance than the atmosphere gas. Accordingly, the atmosphere gas high in thermal resistance intervenes with the provision of the clearance 201, and hence the heat transferred from the second susceptor part 102b″ to the first susceptor part 102a″ also lowers. Thus, a rise in the temperature at the outer peripheral portion of the silicon wafer 101 is suppressed.

The susceptor 102″ of the present embodiment is provided with holes (through holes) 205 which connect the clearance 201 and the P₁ area within the chamber 103 to each other, in the radial direction of the susceptor 102″. The holes 205 can be formed by providing such grooves as formed in the second embodiment at the second susceptor part 102b″. Such a configuration enables prevention of a position displacement of the silicon wafer 101. This effect will be described in detail below.

The atmosphere gas in the clearance 201 thermally expands with a rise in the temperature due to heating. If the holes 205 are not provided, the first susceptor part 102a″ is pushed up by the pressure of the atmosphere gas. This causes a rising force to act on the silicon wafer 101 which comes into contact with the first susceptor part 102a″. As a result, the silicon wafer 101 is moved from its predetermined position. According to the configuration of the present embodiment, however, the thermally-expanded atmosphere gas is degassed into the P₁ area through the holes 205. Thus, the first susceptor part 102a″ is prevented from being pushed up so that the occurrence of the position displacement in the silicon wafer 101 can be prevented. According to the configuration of the present embodiment as well, the possibility that the holes 205 may be blocked off by the epitaxial growth film is low. From this point of view, the present configuration has an advantage over the configuration described in the first embodiment.

Preferably, the size of the holes 205, the number thereof and their layout are suitably set according to the diameter of the silicon wafer 101, the distribution of stress applied thereto, and the like.

If the holes are too small, stress may be concentrated around this area and can cause breakage of the susceptor. Further, since processing the excessively small holes is difficult, consideration of ease of processing is necessary to decide the size thereof. On the other hand, if the holes are excessively large, a temperature distribution occurs in the susceptor and hence the thickness of the formed epitaxial film will not be uniform. Accordingly, the size of the holes may preferably be determined in consideration of this point.

The number of the holes may be one or more, but is preferably provided in plural form where the uniform heating and stress distribution of the susceptor are taken into consideration.

According to the susceptor of the present embodiment as described above, since the clearance is provided between the first susceptor part and the second susceptor part, the temperature of the first susceptor part brought into contact with the outer peripheral portion of the wafer becomes lower than in a susceptor without the clearance when the first susceptor part is heated by the contact of the first susceptor part with the outer peripheral portion thereof. Thus, since the temperature of the outer peripheral portion of the wafer does not suddenly rise more than that at the portion other than the outer peripheral portion, the uniform temperature distribution of the wafer is not interfered. Since the concentration of thermal stress on the portion where the wafer and the first susceptor part come into contact with each other is reduced, it is also possible to reduce breakage of the susceptor and the occurrence of a slip in the wafer.

According to the film forming apparatus of the present embodiment, since the holes which connect the clearance and the inside of the chamber are provided in the radial direction of the susceptor, the atmosphere gas in the clearance is degassed into the chamber through the holes. Accordingly, the first susceptor part is not pushed up even if the atmosphere gas expands due to heating, thereby making it possible to prevent the occurrence of the position displacement in the wafer.

Incidentally, although the present embodiment has described the example in which the silicon wafer 101 is in contact with the second susceptor part 102b″, a clearance may be provided between the silicon wafer and the second susceptor part as shown in FIG. 5. In the above example, the holes (through holes) 205 which connect the clearance 201 and the P₁ area existing in the chamber 103, are provided in the radial direction of the susceptor 102″, but the grooves may be provided in the first susceptor part 102a″.

### Fourth Embodiment

One example of a film forming method using the susceptor shown in FIG. 2 will be explained with reference to FIG. 1. According to the present film forming method, a film uniform in thickness can be grown while the occurrence of a slip is being reduced. Incidentally, the susceptor shown in FIG. 5 may be used instead of the susceptor shown in FIG. 2. The film forming apparatus shown in FIG. 7 or 9 may be used instead of the film forming apparatus shown in FIG. 1.

The silicon wafer 101 is placed on the susceptor 102 as shown in FIG. 2. Described specifically, the outer peripheral portion of the silicon wafer 101 is supported by the ring-shaped first susceptor part 102a, and the other portion thereof is supported by the second susceptor part 102b. The second susceptor part 102b is in contact with the outer peripheral portion of the first susceptor part 102a and disposed so as to block off the opening of the first susceptor part 102a. At this time, the clearance 201 is defined between the first susceptor part 102a and the second susceptor part 102b. Incidentally, the diameter of the silicon wafer 101 can be set to 200 mm or 300 mm, for example.

Then, the silicon wafer 101 is rotated at 50 rpm or so concurrently with the rotating section 104 while hydrogen gas is being allowed to flow under atmospheric pressure or appropriate reduced pressure.

Next, the silicon wafer 101 is heated from 100° C. to 200° C. by the inheater 120 and the outheater 121. The silicon wafer 101 is gradually heated to, for example, 1150° C. indicative of a film formation or deposition temperature.

After it has been confirmed that the temperature of the silicon wafer 101 has reached 1150° C. at the measurement of the temperature by the radiation thermometer 122, the rotational speed of the silicon wafer 101 is gradually increased. Then, a material gas is supplied from the gas supply part 123 to the inside of the chamber 103 via the shower plate 124. In the present embodiment, trichlorosilane can be used as the material gas and introduced from the gas supply part 123 to the inside of the chamber 103 in a state of being mixed with the hydrogen gas used as a carrier gas.

The material gas introduced into the chamber 103 flows downstream toward the silicon wafer 101. New material gases are successively supplied from the gas supply part 123 to the silicon wafer 101 through the shower plate 124 while maintaining the temperature of the silicon wafer 101 at 1150° C. and rotating the susceptor 102 at a high speed of 900 rpm or more, thus making it possible to grow an epitaxial film efficiently at a high deposition rate.

Growing an epitaxial layer composed of silicon, which is uniform in thickness, on the silicon wafer 101 can be possible by rotating the susceptor 102 while the material gas is being introduced. In applications such as power semiconductors, a thick film of 10 μm or more, mostly about 10 μm to 100 μm is formed on a silicon wafer of 300 mm thickness. In order to form the thick film, the number of rotations of a substrate at the film formation may be high, preferably, the rotational speed may be set at 900 rpm or so as described above.

Incidentally, the known method can be applied to the carrying of the silicon wafer 101 into the chamber 103 or the carrying thereof out of the chamber 103.

In FIG. 1, for example, the silicon wafer 101 is carried in the chamber 103 by using an transfer robot (not shown). Assume now that an lifting pin (not shown) penetrating the inside of the rotating shaft 104b is provided inside the rotating section 104. After the lifting pin has been elevated to support the first susceptor part 102a, the lifting pin is further elevated to lift the first susceptor part 102a off the second susceptor part 102b. Further, the first susceptor part 102a is elevated to support the lower surface of the silicon wafer 101 supported by the transfer robot with the first susceptor part 102a. If plural protrusions (not shown) are provided at a surface opposite to the silicon wafer 101, of the first susceptor part 102a, then the silicon wafer 101 can be supported by the protrusions. Then, the silicon wafer 101 is detached from the transfer robot and supported only by the first susceptor part 102a. After the transfer robot has transferred the silicon wafer 101 to the first susceptor part 102a, the robot is retreated from inside of the chamber 103. Next, the first susceptor part 102a having the silicon wafer 101 is lowered in a state in which it remains supported with the lifting pin. Then, the first susceptor part 102a is returned to the initial position thereof. The silicon wafer 101 can be placed on a film forming position on the susceptor 102. After the film forming process has been ended, the silicon wafer 101 is transferred from the first susceptor part 102a to the transfer robot in accordance with an operation inverse to the above and carried out of the chamber 103.

Incidentally, even when the susceptor 102a₁ shown in FIG. 5 is used, the silicon wafer 101 can be carried out in the same manner as described above.

When the susceptor 102 shown in FIG. 2 is configured such that the first susceptor part 102a and the second susceptor part 102b are formed integrally, the silicon wafer 101 can be fed using the Bernoulli effect, for example. For instance, a carrying gas is jetted out radially in the direction of the peripheral edge portion of the silicon wafer from the neighborhood of the central part of the back surface thereof. This causes the Bernoulli effect to occur so that the silicon wafer can be levitated and held. Incidentally, this is similar to the case where the susceptor 102₁ shown in FIG. 5 is used, in which the first susceptor part 102a₁ and the second susceptor part 102b₁ are integrally configured.

The features and advantages of the present invention may be summarized as follows.

For example, in the first embodiment, the first susceptor is provided with the holes through which the atmosphere gas existing between the first susceptor part and the second susceptor part is degassed outside. In the second embodiment, the second susceptor part is provided with the grooves and the rotating section is provided with the holes, respectively. They are installed so as to communicate with one another, whereby the atmosphere gas between the first susceptor part and the second susceptor part is degassed outside through the grooves and the holes. Further, in the third embodiment, the holes are provided in the radial direction of the susceptor, and the atmosphere gas between the first susceptor part and the second susceptor part is degassed outside through the holes. The structure of the susceptor of the present invention is not however limited to these, but may be a structure in which the atmosphere gas between the first susceptor part and the second susceptor part can be degassed outside through the holes defined in the susceptor. However, if the holes are defined in the surface opposite to the heaters, of the susceptor, contaminants such as metal atoms developed in the heating and rotating sections may be moved through the holes to contaminate the wafer. Thus, the holes should be provided at portions other than the surface opposite to the heaters of the susceptor.

Although the film is formed or grown while rotating the silicon wafer in each of the above embodiments, the film may be formed without rotating the silicon wafer.

Although each of the above embodiments has mentioned the epitaxial growth apparatus as one example of the film forming apparatus, the present invention is not limited to it. Other film forming apparatus, such as CVD apparatus or the like, may be used, which supplies a reaction gas to an inside of a film forming chamber and heats a wafer placed within the film forming chamber to form a film in the surface of the wafer.

Further, the present invention can be applied to a case in which a process such as ashing is performed on a wafer while heating the wafer. Namely, according to the susceptor of the present invention, since the temperature distribution of the wafer can be made uniform without causing any position displacement of the wafer, a uniform process can be performed on the wafer.

1. A susceptor comprising: a first susceptor part that is ring shaped; a second susceptor part that is a close fit in the opening of the first susceptor part and is in contact with the outer peripheral portion of the first susceptor part; a clearance of a predetermined size between the first susceptor part and the second susceptor part and between the opening and the outer peripheral portion; and holes through which a gas in the clearance is expelled.

2. The susceptor according to claim 1, wherein the holes through which a gas is degassed are provided in a radial direction of the first susceptor part or in a direction perpendicular to the radial direction.

3. A susceptor on which a substrate is to be placed when a predetermined process is performed on the substrate, the susceptor comprising: a first susceptor part that is ring shaped, the first susceptor part supporting an outer peripheral portion of the substrate; and a second susceptor part which is provided in contact with an outer peripheral portion of the first susceptor part and blocks off an opening of the first susceptor part, wherein the second susceptor part is disposed in such a manner that a clearance of a predetermined size is formed between the substrate and the second susceptor part in which the substrate is supported by the first susceptor part, and disposed in such a manner that a clearance of a size substantially equal to the predetermined size is formed adjoining the former clearance between the first susceptor part and the second susceptor part, and wherein holes through which gas in these clearances is expelled are provided.

4. The susceptor according to claim 3, wherein the holes through which a gas is degassed are provided in a radial direction of the first susceptor part or in a direction perpendicular to the radial direction.

5. A film forming apparatus comprising: a film forming chamber into which a substrate is to be carried; a susceptor on which the substrate is to be placed within the film forming chamber; and a heating section which heats the substrate through the susceptor; wherein the susceptor comprises: a first susceptor part that is ring shaped; a second susceptor part that is a close fit in the opening of the first susceptor part and is in contact with the outer peripheral portion of the first susceptor part; a clearance of a predetermined size between the first susceptor part and the second susceptor part and between the opening and the outer peripheral portion; and holes through which a gas in the clearance is expelled.

6. The film forming apparatus according to claim 5, wherein the holes through which a gas is degassed are provided in a radial direction of the first susceptor part or in a direction perpendicular to the radial direction.

7. The film forming apparatus according to claim 5, wherein the apparatus has a rotating section which rotates the susceptor, and wherein the second susceptor part is provided with grooves, and the susceptor is disposed in such a manner that holes provided in the rotating section and the grooves communicate with one another, thereby expelling a gas in the clearance.

8. A film forming apparatus comprising: a film forming chamber into which a substrate is to be carried; a susceptor on which the substrate is to be placed within the film forming chamber; and a heating section which heats the substrate through the susceptor, wherein the susceptor comprises: a first susceptor part that is ring shaped, the first susceptor supporting an outer peripheral portion of the substrate; and a second susceptor part which is provided in contact with an outer peripheral portion of the first susceptor part and blocks off an opening of the first susceptor part, wherein the second susceptor part is disposed in such a manner that a clearance of a predetermined size is formed between the substrate and the second susceptor part in which the substrate is supported by the first susceptor part, and disposed in such a manner that a clearance of a size substantially equal to the predetermined size is formed—adjoining the former clearance between the first susceptor part and the second susceptor part, and wherein the susceptor is provided with holes through which a gas in these clearances is expelled.

9. The film forming apparatus according to claim 8, wherein the holes through which a gas is degassed are provided in a radial direction of the first susceptor part or in a direction perpendicular to the radial direction.

10. The film forming apparatus according to claim 8, wherein the apparatus has a rotating section which rotates the susceptor, and wherein grooves provided in the second susceptor part communicate with holes defined in the rotating section, thereby expelling a gas in the clearance.

11. A film forming method for forming a predetermined film on a substrate while heating the substrate within a film forming chamber, the method comprising: supporting an outer peripheral portion of the substrate by a first susceptor part that is ring shaped; causing a second susceptor part that is close fit in an opening of the first susceptor part and supports a portion other than the outer peripheral portion of the substrate to contact an outer peripheral portion of the first susceptor part, and to be disposed in such a manner that a clearance having a predetermined size is formed between the first susceptor part and the second susceptor part and between the opening and the outer peripheral portion of the first susceptor part; and forming the predetermined film while expelling a gas which lies in the clearance and is expanded by heating into the film forming chamber.

12. The film forming method according to claim 11, wherein the holes through which a gas is degassed are provided in a radial direction of the first susceptor part or in a direction perpendicular to the radial direction.

13. The film forming method according to claim 11, wherein the gas which lies in the clearance is expelled through the holes that are provided in a radial direction of the first susceptor part or in a direction perpendicular to the radial direction.

14. A film forming method for forming a predetermined film on a substrate while heating the substrate within a film forming chamber, the method comprising: supporting an outer peripheral portion of the substrate by a first susceptor part that is ring shaped; causing a second susceptor part that blocks off an opening of the first susceptor part to be provided in contact with an outer peripheral portion of the first susceptor part, and to be formed in such a manner that a clearance of a predetermined size is formed between the substrate and the second susceptor part in which the substrate is supported by the first susceptor part, and in such a manner that a clearance of a size substantially equal to the predetermined size is formed between the first susceptor part and the second susceptor part; and thus forming the predetermined film while expelling the gas in these clearances.

15. The film forming method according to claim 14, wherein the holes through which a gas is degassed are provided in a radial direction of the first susceptor part or in a direction perpendicular to the radial direction.

16. The film forming method according to claim 14, wherein the gas which lies in the clearance is expelled through the holes that are provided in a radial direction of the first susceptor part or in a direction perpendicular to the radial direction.
